(19) United States
(12) Patent Application Publication
(10) Pub. No.: US 2014/0158193 A1
(43) Pub. Date: Jun. 12, 2014

(54) STRUCTURES AND METHODS OF FORMATION OF CONTIGUOUS AND NON-CONTIGUOUS BASE REGIONS FOR HIGH EFFICIENCY BACK-CONTACT SOLAR CELLS

(71) Applicant: Solexel, Inc., Milpitas, CA (US)

(72) Inventors: Anande Desphande, San Jose, CA (US); Pawan Kapur, Burlingame, CA (US); Heather Deshazer, Palo Alto, CA (US); Mehrdad M. Moslehi, Los Altos, CA (US); Virendra V. Rana, Los Gatos, CA (US); Sean M. Seutter, San Jose, CA (US); Pranav Anbalagan, Milpitas, CA (US); Benjamin E. Rattle, Oakland, CA (US); Solene Coutant, Oakland, CA (US); Swaroop Kommera, Milpitas, CA (US)

(21) Appl. No.: 13/905,113

(22) Filed: May 29, 2013

Related U.S. Application Data
(63) Continuation-in-part of application No. 13/807,631.
(60) Provisional application No. 61/652,833, filed on May 29, 2012.
(60) Provisional application No. 61/816,830, filed on Apr. 29, 2013.
(60) Provisional application No. 61/827,252, filed on May 24, 2013.
(60) Provisional application No. 61/521,754, filed on Aug. 9, 2011.
(60) Provisional application No. 61/521,743, filed on Aug. 9, 2011.

(51) Int. Cl. H01L 31/0236; H01L 31/18

(52) U.S. Cl. CPC H01L 31/02363; H01L 31/1884
USPC 136/256; 438/98

(57) ABSTRACT

Fabrication methods and structures relating to back contact solar cells having patterned emitter and non-nested base regions are provided.

### CROSS-REFERENCE TO RELATED APPLICATIONS

This application claims priority to U.S. Provisional Patent Application Ser. Nos. 61/658,833 filed May 29, 2012, 61/816,830 filed Apr. 29, 2013, and 61/827,252 filed May 24, 2013, all of which are hereby incorporated by reference in their entirety.

This application is a continuation-in-part of U.S. application Ser. No. 13/807,631 filed Dec. 28, 2012 which is a 35 U.S.C. 371 National Stage of P.C.T application PCT/US12/00348 filed Aug. 9, 2012 which claims priority to U.S. Provisional Patent Application Ser. Nos. 61/521,754 filed Aug. 9, 2011 and 61/521,743 filed Aug. 9, 2011, all of which are hereby incorporated by reference in their entirety.

### FIELD

The present disclosure relates in general to the fields of photovoltaics. More particularly, the present disclosure relates to the methods, architectures, and apparatus related to high-efficiency back-contact photovoltaic solar cells.

### BACKGROUND

Achieving high cell and module efficiencies in conjunction with a low fabrication cost is critical in solar cell development and manufacturing. In some instances, back contact back junction solar cell architecture (Back Contact/Back Junction or BC/BJ) is capable of achieving very high conversion efficiencies. Often, existing back contact, back junction solar cells have patterned emitter junction and cell metallization layers which are formed on the non-sunnyside (backside) and the sunnyside (frontside) has no metallization in order to accomplish an un-obstructed, maximum coupling of the sunlight.

In a typical back contact/back junction crystalline silicon architecture (hence forth, BC/BJ) solar cell, the emitter junction and highly doped base diffusion regions may be formed on the solar cell backside (non-sunny side) to provide contact to majority of the solar cell substrate volume which is base. Further, highly doped base diffusion regions are formed below base metal contact area to reduce contact recombination, and to reduce base metal contact resistance. In a typical high efficiency BC/BJ solar cell, base metal and emitter metal are often patterned and contained within the base and emitter diffusion areas, respectively, such that the base metal never runs on top of the emitter diffusion, even if it is separated by oxide. This is henceforth, referred to as the nested metal approach, where the metal of each kind is nested within its respective diffusion. An advantage of the nested approach is that it provides immunity to shunting of the metal to the diffusion of the opposite polarity. A disadvantage is that that the minimum metal width of the base dictates the minimum base diffusion width, which in turn, renders the base diffusion to be a relatively larger fraction of the backside of the solar cell, causing a reduction in the emitter fraction and increased electrical shading. This in turns requires that wafer or silicon absorber have a very high minority carrier lifetime (e.g., >1 millisecond range) to ensure that the minority carriers do not recombine in the base while under the base diffusion. Thus, the overall manufacturing cost of the solar cell increases due to the higher cost of the higher quality wafers.

### BRIEF SUMMARY

Therefore, a need has arisen for fabrication methods and designs relating to doped regions and metallization for solar cells. In accordance with the disclosed subject matter, methods, structures, and apparatus for non-nested base diffusion patterns and metallization of solar cells are provided. These innovations substantially reduce or eliminate disadvantages and problems associated with previously developed solar cells.

According to one aspect of the disclosed subject matter, fabrication methods and structures relating to multi-level metallization of solar cells are described. In one embodiment, a back contact solar cell comprises a substrate having a light receiving frontside surface and a backside surface for forming patterned emitter and non-nested base regions. Interdigitated doped emitter and base regions are formed on a backside surface of a crystalline semiconductor substrate. A patterned electrically insulating layer stack comprising a combination of at least a doped layer and an undoped capping layer is formed on the patterned doped emitter and base regions. A contact metallization pattern is formed comprising emitter metallization electrodes contacting the emitter regions and non-nested base metallization electrodes contacting the base regions wherein the non-nested base metallization electrodes are allowed to go beyond the base regions to overlap at least a portion of said patterned insulator without causing electrical shunts in the solar cell.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, nature, and advantages of the disclosed subject matter may become more apparent from the detailed description set forth below when taken in conjunction with the drawings in which like shapes indicate like features and wherein:

FIG. 1A is a diagram showing a top view of a solar cell backside showing a nested base design;

FIG. 1B FIG. 1A is a diagram showing a top view of a solar cell backside showing a non-nested based design;

FIG. 2A is a diagram showing a top view of a solar cell backside showing a uniform distributed contiguous/non-nested base design;

FIG. 2B is a diagram showing a top view of a solar cell backside showing a uniform distributed selective non-contiguous/non-nested base design;

FIG. 3A is a diagram showing a top view of a solar cell backside showing a uniform base pattern with parallel base design and FIG. 3A′ is a corresponding screen print design for forming the pattern of FIG. 3A;

FIG. 3B is a diagram showing a top view solar cell backside showing of an alternative uniform base pattern with staggered base design and FIG. 3B′ is a corresponding screen print design for forming the pattern of FIG. 3A;

FIG. 3C is a diagram showing a top view solar cell backside showing an alternative non-nested base pattern;

FIG. 4 is a diagram showing a top view of a solar cell backside of a non-nested base pattern highlighting exemplary dimensions;

FIG. 5 is a diagram showing a distributed emitter and base laser pattern;

FIG. 6A is a photograph showing selective emitter (SE) and base openings;

FIG. 6B is a photograph showing emitter and base contacts inside selective emitter (SE) and base openings;

FIG. 7A is a diagram showing laser annealing damage in selective emitter openings;

FIG. 7B is a diagram showing laser annealing damage in selective base openings;

FIG. 7C is a diagram showing laser annealing damage in contacts in selective emitter openings;

FIG. 7D is a diagram showing laser annealing damage in contacts in selective base openings;

FIG. 8A is a photograph showing laser ablation spots before anneal;

FIG. 8B is a photograph showing laser ablation spots after anneal with a 30 nanoseconds UV laser;

FIG. 9 is a Minority Carrier Lifetime (MCL) map of a silicon substrate after oxide ablation, specifically showing MCL improvement obtained after laser annealing of ablation spots;

FIG. 10A is a diagram of a multi-station substrate laser processing tool and FIG. 10B is a diagram of the tool of FIG. 10A holding multi-wafers;

FIGS. 11A through 11I are cross-sectional diagrams showing a solar cell after processing steps during an amorphous silicon mask process flow;

FIG. 12 is a Minority Carrier Lifetime (MCL) map of a silicon substrate after oxide ablation, specifically showing MCL improvement obtained when amorphous silicon is used as a hard mask;

FIG. 13A is a general process flow for the formation of a back-contact back-junction solar cell; and

FIG. 13B is a representative manufacturing process flow for forming a back-contact/back-junction cell.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

And although the present disclosure is described with reference to specific embodiments, such as crystalline silicon and other fabrication materials, one skilled in the art could apply the principles discussed herein to other materials, technical areas, and/or embodiments without undue experimentation.

The disclosed subject matter provides various structures and manufacturing methods for high-efficiency back-junction/back contacted solar cells specifically using thin crystalline semiconductor absorbers such as monocrystalline silicon with the cell absorber layer (or substrate), preferably ranging in thickness from about less than one micron (1 μm) up to about one hundred microns (100 μm), and even more particularly ranging in thickness from about one micron (1 μm) to about fifty microns (50 μm). The cell structures and manufacturing methods provided also apply to thicker crystalline semiconductor substrates or absorbers, ranging in thickness from about 100 μm to about 200 μm (which also includes the thickness range for more conventional CZ or FZ wafer thicknesses). The crystalline solar cell substrates may be formed either using chemical-vapor-deposition (CVD) methods including epitaxial growth (such as atmospheric-pressure epitaxy) or other crystalline silicon material formation techniques (including but not limited to the so-called kerfless slicing or exfoliation methods utilization proton implantation, metal-stress-induced exfoliation, or laser). Various embodiments of manufacturing methods as it pertains to all aspects of processing very thin crystalline semiconductor solar cell substrates may be extended to other types of materials and to wafer based approaches, including kerfless cleavage methods such as the implantation-assisted wafer cleavage methods. Key attributes of various cell embodiments provided include substantially reduced semiconductor (e.g., silicon) material consumption, very low manufacturing cost, high cell efficiency, and relatively high energy yield, thus, improved solar photovoltaic module performance. Specifically, this stems from the combinations of the unique cell design architectures and manufacturing methods of the disclosed subject matter, which entail manufacturing back junction/back contacted solar cells using thin crystalline semiconductor layers, yielding very high conversion efficiency on thin crystalline semiconductor substrates, yielding very low cost.

And although the present disclosure is described with reference to specific embodiments, such as back contact solar cells using monocrystalline silicon substrates having a thickness in the range of 10 to 200 microns and other described fabrication materials metallization layers, one skilled in the art could apply the principles discussed herein to front contact cells, other fabrication materials including alternative semiconductor materials (such as gallium arsenide, germanium, multi-crystalline silicon, etc.), metallization layers comprising metallization stacks, technical areas, and/or embodiments without undue experimentation. The novel doped region formation embodiments of this invention, while applicable to any architecture such as front contacted, back-contact/back junction or even back contact/front junction solar cells, are specifically illustrated in this invention with respect to the back contact/back junction crystalline silicon architecture (hence forth, BC/BJ).

The present application provides robust methods to accomplish non-nested base metal design. Non-nested metal allows the heavy base diffusions to be smaller than the width of the base metal, while ensuring that there is no path for breaching the electrically insulator layer, such as oxide, between base metal and the underlying emitter. This is accomplished by ensuring that the dielectric stack separating base metal from the emitter diffusion is free of through-dielectric pin-holes, allowing a non-nested base metal design without causing electrical shunts. In a specific embodiment, this can be realized using several (e.g., at least two) APCVD deposited doped and undoped (capping) dielectric layers. These are typically silicon dioxide (SiO2) layers, but may also include silicon nitride (SiNx) and/or amorphous silicon (a-Si), and/or aluminum oxide (Al2O3) layers (doped and/or undoped in each case). By depositing several (at least two) APCVD layers in different runs, the statistical probability of lining up of any pin-holes through the entire dielectric stack is dramatically reduced. In another embodiment, to further provide robustness a thermal oxide step can be added after, before, or in-between the APCVD dielectric layers to ensure that there are no shunting pinholes. (for more detail see U.S. patent application Ser. No. 13/807,631 to which the application claims priority and is incorporated by reference in its entirety).

The non-nested metallization design can be used either with contiguous base or non-contiguous (discrete base array) base diffusions. In the case of contiguous base diffusions, the base may be a series of straight lines (columns). The base metal overlaps with these diffusions, while not necessarily being contained inside the diffusions. For the case of non-contiguous base diffusions, these diffusions can be isolated islands which only surround where isolated base contacts are required. The diffusions can be circular, rectangular or other geometrical shapes, while connected by base metal line to each other.

An advantage of non-contiguous base diffusions is that it can minimize the base resistance through silicon, while keeping the emitter fraction constant (at a relatively high level), for a given metal pitch. The reduction in the base diffusion area, while allows a relaxed lifetime of the material for BC/BJ cells, increases the distance between base diffusions for a given metal pitch, hence, causing a potential degradation of fill factor of the solar cell through increase in base resistance. The enabling embodiments of this invention relax these restrictions and facilitate design and fabrication of high efficiency solar cells. This invention allows the non-nested base design architecture to afford effectively lower base resistance through the greater flexibility of non contiguous selective/distributed base diffusion

In one embodiment, the base islands are isolated (discrete base islands), but co-linear (or arranged along columns) being connected by a single base metal line which connects to silicon base periodically through the base contacts inside the isolated base islands. By necessity, this design will be non-nested as the connecting base metal line runs between isolated base diffusion islands, on top of the emitter areas (over the dielectric layer covering doped emitter regions). Hence, the success of the non-contiguous base pattern design is highly dependent on ability to run non-nested base metal without shunting it. This is ensured by the aforementioned process techniques. In another instance, the distributed base islands under a given Base metal line has more than a single co-linear row (or column); can have two or multiple rows (or columns) with offset island positions. The general architecture provides flexibility for getting better electrical performance. The details of the structure and advantages of these non-contiguous schemes are outlined in the subsequent sections.

A distributed, non-contiguous base diffusion (such as discrete base islands as shown U.S. patent application Ser. No. 13/807,631 to which the application claims priority and which is again incorporated by reference in its entirety herein) and contact formation scheme, comprising of novel patterning and diffusion methods, in the context of non-nested metal architectures, where the base metal (defined as the metal contacting the base diffusion area) is free to run over emitter diffusion area (covered by the dielectric layer over the doped emitter regions) on top of a dielectric passivation layer (and vice-versa if desirable) in a robust, shunt-free, manner. The design can also be referred to as Spot in Spot (SIS). The name derives its origin from the fact that the isolated and non-contiguous contact spot is opened inside the non-contiguous base diffusion area. The doped dielectric films are patterned forming non contiguous areas of highly doped regions (n-type or p-type) of the same type as the relatively lightly doped base (n type or p-type). The non-contiguous (or discrete islands of) highly doped base structures are placed in a geometrically optimal fashion, while still under the base metal, so as to minimize their distance from each other, thus minimizing the diffusion resistance losses through the lightly doped base. For ultrathin solar cell absorbers, the combination of these diffusion patterns and optimized diffusions with doped dielectric films can also serve as good electrical insulators to reduce the risk of electrical shorts or shunts between base and emitter regions of solar cells.

There are unique and independent benefits of these aspects as detailed below. We disclose a few design concepts to illustrate the non-nested and/or non-contiguous base architectures. Benefits of this invention, particularly in the context of high-efficiency crystalline semiconductor (including back-contact/back-junction mono-crystalline or multi-crystalline silicon) solar cells are also outlined.
A) In the commonly used architecture, the base metal is nested inside the base diffusion (specifically put in for contacting to the lightly doped base) to avoid cell shunting. This restriction of metallization nesting and the impact of the resulting design rules require a minimum base heavy diffusion area dictated by minimum base metal width. This in turn, reduces the emitter fraction and requires a costly, high lifetime wafer to ensure that the photo excited carriers do not recombine under the long base diffusions and are able to get to the emitter. Non nested base allows higher emitter fraction area on the backside, a desirable cell design attribute for achieving high cell efficiencies. Non-nesting of the metallization pattern and the resulting enhanced emitter area fraction lead to much less minority carrier recombination losses (as is highly desirable particularly with ultrathin cells with absorber thickness below about 100 microns, preferably below 80 microns, and/or large-area cells with cell area at least 125 mm×125 mm and preferably 156 mm×156 mm or larger). The non nested base metal is afforded by good dielectric insulation offered from dielectric layers. The cell design progression is based on the following constraints. The minimum Base and Emitter metal widths are first determined based on the desired metal line resistance requirements, and based on the available resolution of the method utilized to pattern the line width, with picoseconds or femtosecond laser ablation one method of direct patterning. For a given cell size (area) and the maximum thickness of the metal (constrained by cost and stress on to the absorber substrate), the minimum metal line width is determined. This is the case for the conventional single metal level metallization. For the case of a multi-level (dual level one embodiment of this invention for multi-level cell metallization), the metal lines touching the cell contacts can be made even more resistive (because they carry electrical currents locally for short distances before they are extracted vertically through vias connected to the second level metal or metal-2 (M2), separated from metal-1 (M1) by an interlayer dielectric or electrically insulating backplane), yielding flexibility to go to smaller widths. Once the metal width is fixed using aforementioned criteria, the conventional nested architecture then requires base diffusion to be wider than this metal width by the required design rule governed by the patterning alignment resolution, leading to relatively large base diffusion areas and relative loss in emitter area fraction. This, in turn, places a stringent requirement on the minority carrier lifetime or electrical quality of the absorber substrate, hence, making it more expensive. The proposed non-nested approach overcomes the above constraint and allows a much larger emitter fraction. This results in lowering the lifetime requirement for equivalent efficiency performance, thus, reducing the substrate cost. The embodiments of this invention also enables back junction and back contacted architecture to be compatible with thinner substrates which may be grown with modest and not very demanding quality, i.e., not stringently high bulk lifetime without loss in performance. An example of this substrate is the epitaxially grown silicon on top of porous silicon which can yield bulk lifetimes in excess of 300 μs to 500 μs for n-type epitaxial silicon growth, but typically not in excess of 1 ms. Another example is to start with a relatively low lifetime (200 to 500 μs) CZ wafer and thin it down to between 5 μm to 100 μm in general, but preferably between 20 μm to 80 μm range. Thus, this invention not only reduces the cost of the conventional back contacted architectures (due to less demanding requirements for the silicon substrate quality), it is paramount for enabling very high efficiency back contact back junction thin mono-crystalline or multi-crystalline solar cells.
B) Non-nested architecture can either have a contiguous or a non-contiguous (discrete islands of) base. The non-contiguous base (also referred to as distributed base or discrete island base design) is where dielectric is patterned to form the discrete base diffusion islands sporadically and non-continuously (akin to islands of base diffusion in a contiguous sea of emitter), thus, providing the flexibility of placing these diffusions and the ensuing contact at will according the needs of the high efficiency design. Non-contiguous scheme along with the non-nested base allows myriad design possibilities.
   1. In one embodiment of design it allows a reduction in the distance (hence, a reduction in the base resistance) between one base diffusion island to the nearest islands, for a given metal pitch.
   2. BC/BJ cells are mostly covered with emitter regions on the backside (non sunny side) of the solar cell, with the base diffusion regions intertwined in the sea of emitter. With non-nested and non-contiguous base concept, all the emitter regions can remain continuous with much larger emitter fraction effectively increasing overall carrier collection efficiency of the solar cell.
   3. Non-nested and non-contiguous base design allows the possibility of increasing emitter fraction area by reducing the highly doped base diffusion areas needed to reduce contact recombination this helps minimize electrical shading without any penalty in diffusion resistances.
C) The ability to afford wider metal width through non contiguous base design allows significant cost savings. It affords the design flexibility of not having a fully connected base i.e., segmented diffusions or discrete islands of base, which in turn allows higher emitter fraction area and lower base to base pitch.

There are various requirements for design and fabrication of high-efficiency, cost-effective solar cell. These are elucidated below for a non nested, non contiguous base (i.e., distributed or discrete base islands). The general method can be extended to a multi-level metallization scheme and is equally applicable to both conventionally thick solar cells as well as very thin silicon solar cellsError! Reference source not found. Error! Reference source not found. Very thin (e.g., thinner than about 80 micron thick absorber layer) solar cells utilizing the methods and structures of this invention include ultrathin crystalline silicon solar cells with crystalline silicon absorber layers in the thickness range of a few microns to 10's of microns, formed by epitaxial lift-off, chemical etch based thinning of wafers (e.g. CZ wafers of starting thickness between 130 microns to 200 microns), proton implant, stress-induced splitting, laser splitting, or other thin silicon slicing techniques.

1. Method of putting an electrically insulating dielectric layer below metal and diffusion (by deposition, screen print, etc.), where this layer serves both as a very effective dielectric to separate metal from the silicon, as well as the source of dopants to form diffusions in the base and the emitter areas of the solar cells.

2. Method of patterning the base diffusions and forming contact areas through the dielectric to connect to the metal.

3. Method of depositing and pattering metal

For step 1, techniques such as atmospheric chemical vapor deposition (APCVD), or patterned screen printing can be used to deposit doped dielectric films. Care has to be taken to ensure that the choice of dielectric films and technique is suitable to ensure good optical quality and good contacts to both n and p-type diffusions in silicon. For blanket deposition techniques such as APCVD (and/or plasma enhanced CVD), high temperature furnace anneal can be used to drive in the dopants. After deposition of the diffusion source dielectrics these films are preferably annealed at a relatively higher temperature (typically between 900° C. and 1150° C.) to drive the dopant into the silicon substrate. Furnace anneal is critical aspect of forming diffusions. Care has to be taken to form these diffusions by altering the dopant concentrations and drive in furnace anneals to achieve very low surface recombination velocity and forming a good emitter. In one embodiment of this disclosure, dielectric material for base and emitter diffusion comprises of doped APCVD silicon oxide with at least one of the doped dielectric layer having a capping layer of undoped dielectric (p or n-type silicon oxide, referred to as Boron doped glass, BSG for p-type, or phosphorous doped glass, PSG for n-type); these layers are subsequently patterned using pulsed picoseconds (or pulsed femtoseconds) laser, which is able to remove oxide while stopping on silicon without causing significant ablation damage it. The patterning of doped APCVD layer of one kind (such as BSG), followed by deposition of APCVD layer of the other dopant type (such as PSG), allows both types of doped layers (BSG and PSG) to be in contact with silicon at pre-specified patterned areas. These doped oxide layers serve as the source of Boron and Phosphorous which ultimately diffuses in silicon to form emitter and base diffusions, respectively. The fractional area of contact with silicon of each layer is determined by the pattern geometry. When this system with the doped layers is annealed at higher temperature, the backside of the resulting solar cell consisting of both emitter (made from BSG) and base (made from PSG) diffusions is formed concurrently. The individual fractions of these diffusions are precisely controlled and dictated by the pre-determined laser direct write ablation pattern. Alternatively, screen printed dopant paste/inks may be used for forming patterned diffusion. A key requirement for these dielectric layers is to electrically isolate absorber layer with diffusions from the metal layer. The metal layer should only contact the absorber where it is intended to do so by opening explicit contact holes. The choice of the dielectric material should be such that it is free of pinholes and is conducive to produce a good back mirror in conjunction with the cell metallization layer for optimal light absorption in the solar cell. Presence of pinholes is undesirable as it provide a shunting path for current between the non-nested base metal and the emitter.

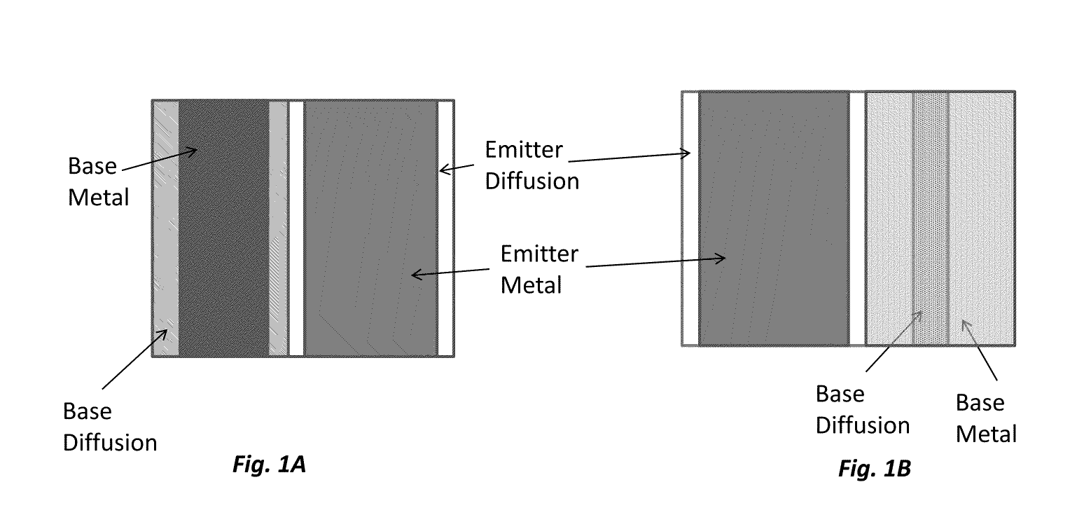

For step 2 related to patterning methods for diffusions, patterning can be done using blanket deposition followed by laser ablation or using standard lithography/etching techniques. The dielectric layer can also be directly patterned using an appropriate dopant paste or liquid using screen printing or stencil printing or inkjet printing (or aerosol jet printing). Conventional BC/BJ solar cells FIG. 1 have interdigitated nested metal design where emitter and base metal lines are exclusively within the interdigitated emitter and base diffusions respectively. The key embodiment of this invention pertains to the formation of non-nested base diffusion patterns in both interdigitated and non-interdigitated emitter and base diffusions. As described in previous section the base diffusion can be either contiguous or non-contiguous.

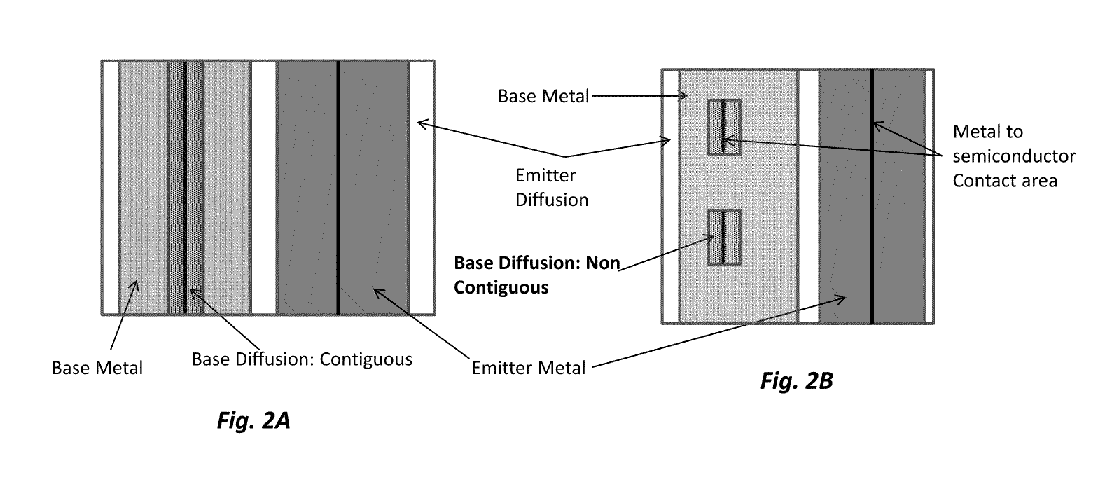

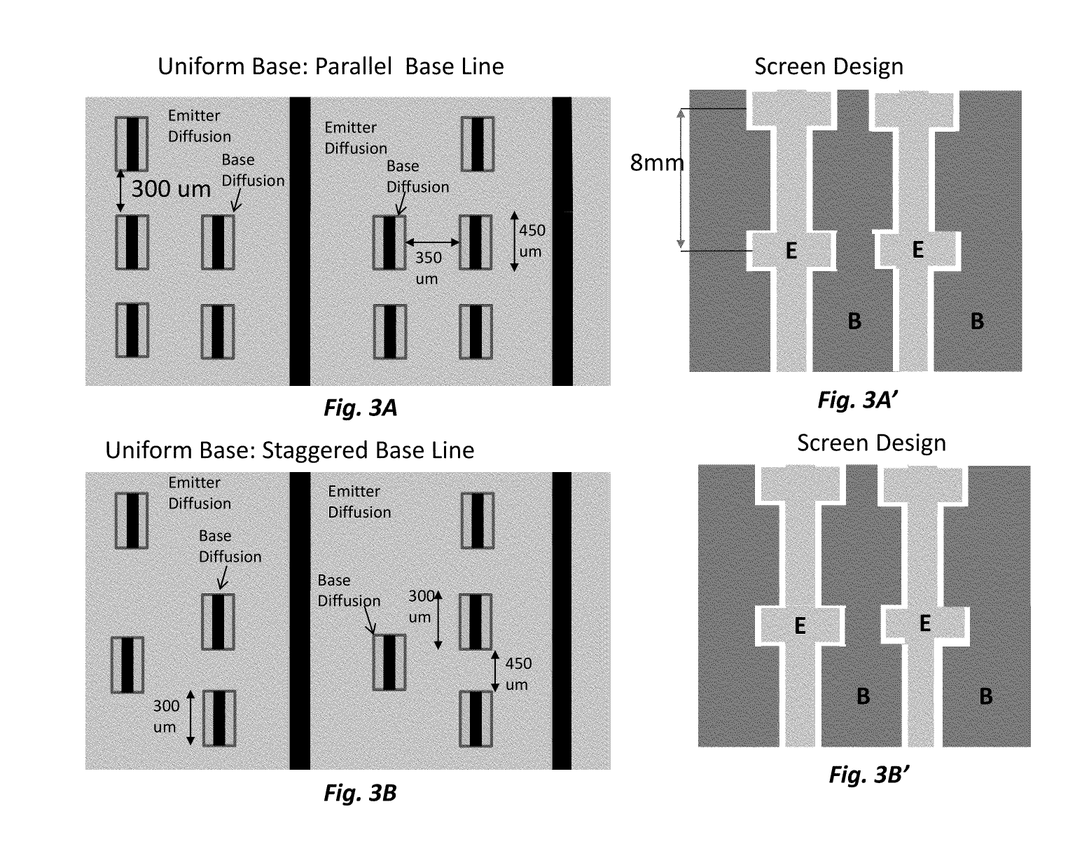

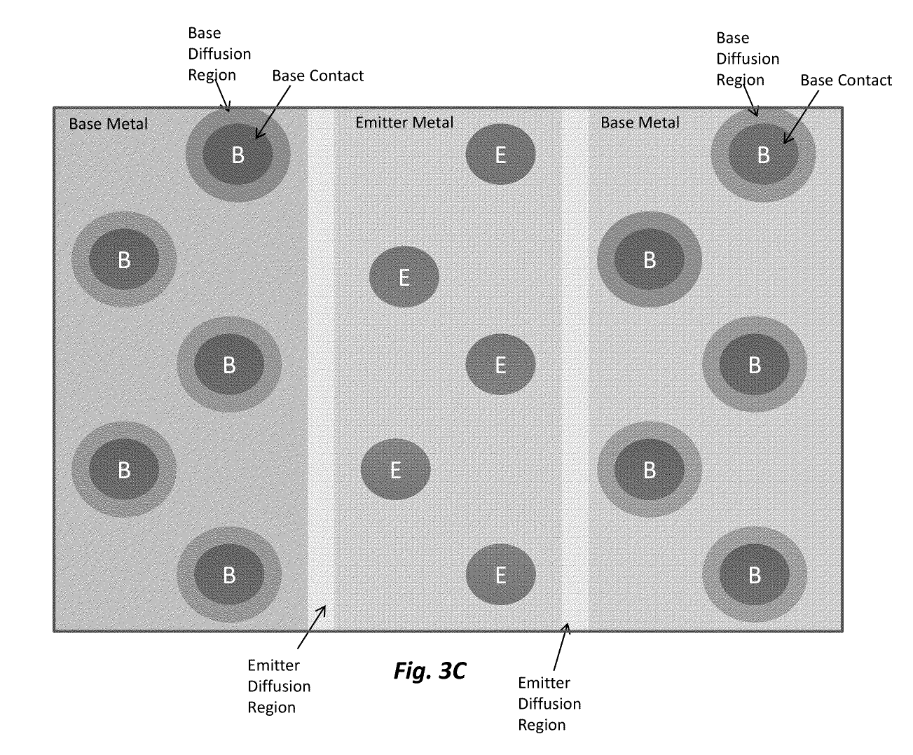

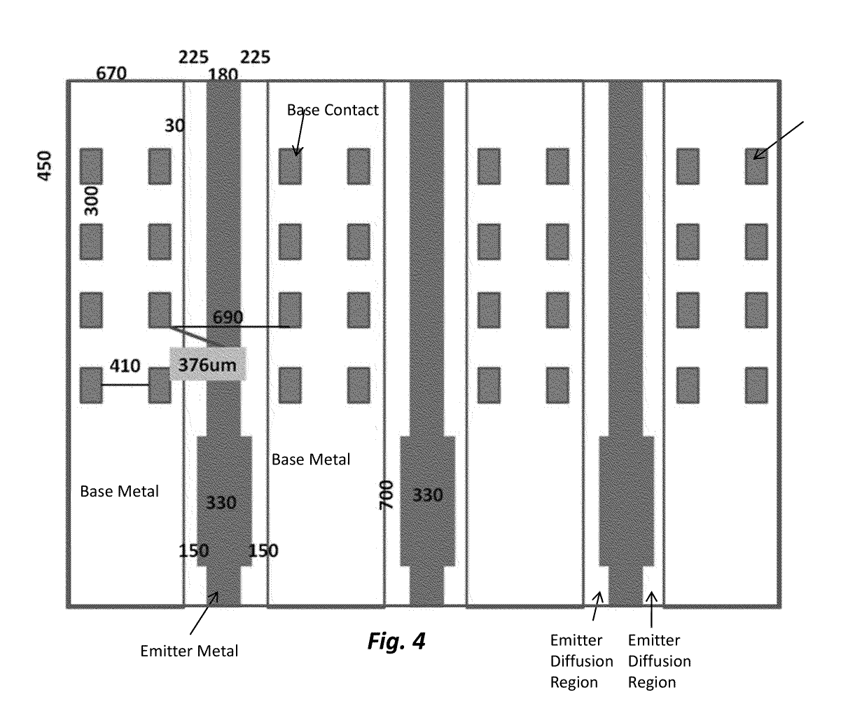

The pattern of contiguous/non-nested design and non-contiguous/non-nested base is described in FIG. 2. The key enabler of the non-nested design is a truly insulating dielectric which allows base metal to run over the emitter diffusions without the risk of killer shunts. As discussed above, non-contiguous base can be utilized for a variety of purposes such as but not limited to reducing base diffusion resistance to gain fill factor, and reducing the base diffusion areas for improving electrical shading. After formation of base diffusion areas the contact holes are formed either by laser ablation or by using standard lithography and etch technique. Various designs within the aforementioned non-contiguous paradigm are shown in FIGS. 3a, 3b and 3c. As shown in FIG. 3a, the emitter fraction area is increased to reduce the current collection loss in the base diffusion areas through reduction in electrical shading. Pitch between the base diffusion and contact area percentage can be further optimized to get same diffusion resistance with better current collection ability. Alternatively, the design can be altered such as shown in FIGS. 3b and 3c to further reduce base diffusion resistance, while not compromising electrical shading. This design embodiment is especially advantageous for thin mono crystalline solar cells where fill factor is limited by high base resistances and/or where Front surface field may not be desirable or possible.

Finally, for step 3 related to metal deposition and patterning (or direct write deposition of the patterned metal layer), several methods can be deployed. This includes techniques such as metal sputtering or evaporation on top of the aforementioned dielectric layer. The deposited metal, in turn, can be patterned and isolated to form base and emitter metal using techniques such as pico second based laser ablation. Alternatively, any of the several direct write techniques such as, but not limited to, screen printing, stencil printing, masked thermal (or arc or plasma) metal spray, inkjet or aerosol printing followed by anneal or activation step can be used to form base and emitter metal. In the case of contiguous design, the base and emitter pitch can be same, making the metal pattern symmetric for both emitter and base metal which is ideal for optimal solar cell current collection. In the ensuing description, a specific process method is detailed for achieving the non-nested and the non-contiguous solar cell design. Although, the method is described in the context of back-contact/back-junction thin mono-crystalline silicon solar cells using epitaxial silicon lift-off methods, it can be used for solar cells of any thickness including standard crystalline silicon wafer-based cells (for example in the thickness range of 100 μm to 200 μm using CZ or FZ wafers). A flow described in Table 1 below.

TABLE 1
Copper Plating Metal 2 based process for epitaxial solar cells

1. Porous Silicon
2. Silicon Epitaxy
3. Front-End All-Dry Process Sequence of APCVD Dielectric
Depositions and Laser Ablation Patterning, and Thermal
Anneal (Through Base and Emitter Contact Openings)
4. Base and Emitter Contact Metallization (Patterned)
5. Lamination + Release*
6. Frontside Texture and Passivation
7. Back-End Final Cell Metallization (Patterned M2)
Using Copper Plating

A thin doped dielectric layer with a similar dopant type as desired for the emitter (p-type Boron in one embodiment) is deposited on the substrate using either APCVD, PECVD, thermal diffusion (from gas based dopant sources), or using direct, patterned, writing methods such as screen print, inkjet or aerosol jet printing. In the case of the blanket deposition of dopant films, post deposition, the dielectric film is etched using picoseconds laser ablation. The etch pattern mirrors the base and emitter regions in silicon (with emitter coming from the patterned layer, and the base coming from the subsequent dielectric film deposition) and can either be contiguous or non-contiguous. This is followed by the deposition of second dielectric film with the opposite type of dopant (phosphorous) for forming the highly doped base diffusion areas. Alternatively, the second dopant layer can be deposited using a direct write method. This is followed by a thermal anneal to activate both types of dopants in one step. This anneal is may be an inert gas environment such as in nitrogen or argon, and can optionally be followed by an anneal at the same temperature in an oxygen-containing environment for a short time. The purpose of the oxygen environment is to form a thermal oxide interface through the dielectric layers, once the dopant has been diffused. This is followed by another pico-seconds laser ablation of oxide for forming the contact openings for the subsequent metallization connections to the absorber layer base and emitter regions. A thin metal (preferably comprising aluminum or an alloy comprising aluminum and silicon) is deposited either using blanket plasma sputtering or evaporation or ion beam deposition. This requires subsequent patterning which can be achieved using a myriad techniques including, but not limited to a pico-second laser ablation using a suitable laser wavelength such as near infrared wavelength. Alternatively, a direct write or screen printing (or aerosol printing, inkjet printing, and stencil printing) of a pre-patterned metal layer (for example, a suitable screen printable aluminum and/or aluminum-silicon alloy paste) can be deployed. In certain cases, this metal deposition needs to be followed by sintering or anneal to cure and activate the patterned metal layer. In the specific process of involving thin mono-crystalline silicon solar cells using epitaxial silicon lift off methods, the thin silicon layer is then can be attached to a second permanent carrier to continue the remaining cell processes such as texture, passivation and metallization. A variation of the above process flow is described in Table 2 below. In this flow, the process flow is identical up to the very last metallization step. The copper plating flow is replaced by a dry PVD (such as evaporation and/or plasma sputtering) based metal deposition in conjunction with using laser (can be a pulsed nano-second laser) to isolate and pattern the PVD metal layer.

TABLE 2
DRY PVD (Plasma Sputtering or Evaporation or Another
PVD) Metal 2 based process for epitaxial solar cells

1. Porous Silicon
2. Silicon Epitaxy
3. Front-End All-Dry Process Sequence of APCVD Dielectric
Depositions and Laser Ablation Patterning, and Thermal
Anneal (Through Base and Emitter Contact Openings)
4. Base and Emitter Contact Metallization (Patterned)
5. Lamination + Release*
6. Frontside Texture and Passivation
7. Back-End Final Cell Metallization (Patterned M2) Using
PVD Metal (e.g., Aluminum with NiV cap) and Pulsed
Nanoseconds Laser Ablation Patterning of PVD Metal

Yet another process flow is a variation of the above flow for thin wafer based solar cell is shown in Table 3 below. Here, instead of growing epitaxial silicon, a standard CZ wafer can be thinned down to make a very high efficiency solar cell. Note, that there is no porous silicon, epitaxy and release steps, instead these steps are replaced by a saw damage removal step and an etchback step after lamination to thin down the wafer.

TABLE 3
DRY PVD (Plasma Sputtering or Evaporation or Another
PVD) Metal 2 based process for CZ wafers

1. Saw Damage Removal
2. Front-End All-Dry Process Sequence of APCVD Dielectric
Depositions and Laser Ablation Patterning, and Thermal
Anneal (Through Base and Emitter Contact Openings)
3. Base and Emitter Contact Metallization (Patterned)
4. Lamination
5. Silicon etch back, Frontside Texture and Passivation
6. Back-End Final Cell Metallization (Patterned M2) Using
PVD Metal (e.g., Aluminum with NiV cap) and Pulsed
Nanoseconds Laser Ablation Patterning of PVD Metal

Finally, it is also possible to remove the laser damage created by using picoseconds (or femtoseconds) laser for both contiguous and non-contiguous (SIS) architectures by using either wet or dry processes. The dry method to reduce/eliminate laser damage is to do a laser anneal after opening the laser contacts. This can be done using nano second laser. Another way to remove laser damage is to use a hard mask (typically a-Si), pattern the hardmask, and wet etch the oxide using the hardmask. This way the pico second laser does not “see’ the silicon.

Laser Annealing of Laser-Induced Ablation Damage.

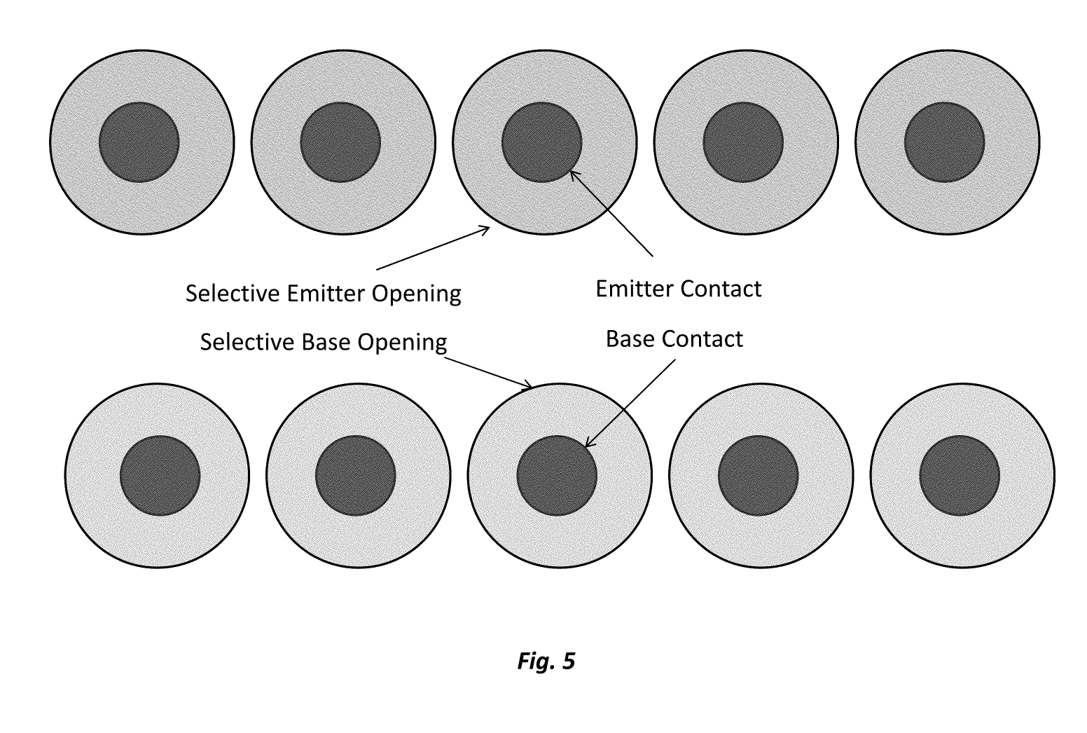

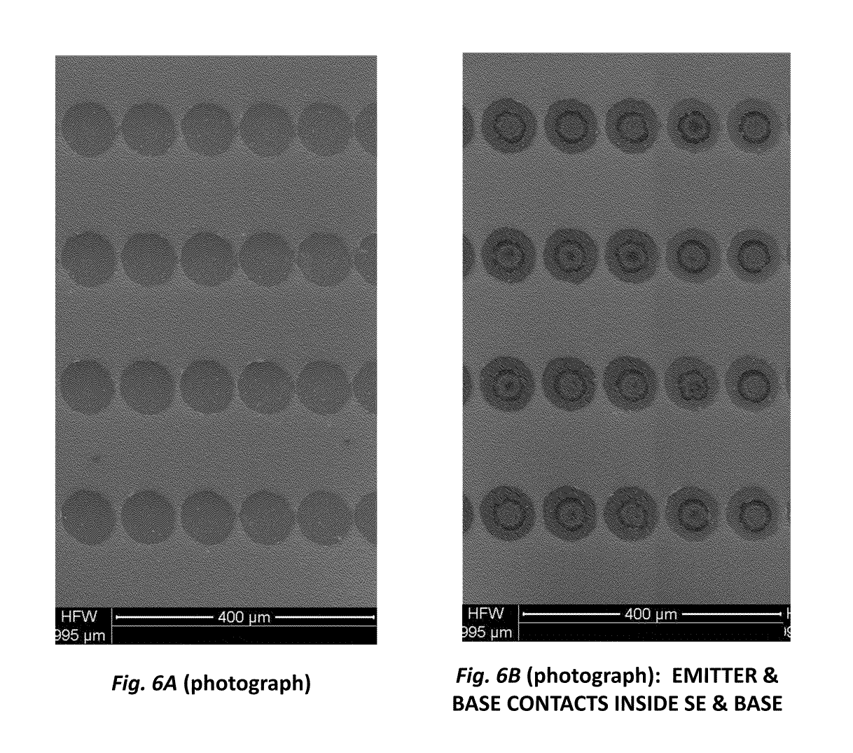

The laser ablation of transparent passivation layers results in at least some laser induced damage in the silicon substrate. Since the passivation layer such as silicon oxide and aluminum oxide are transparent to wavelengths down to UV (355 nm), the removal of the transparent layers takes place by the melting and evaporation of the silicon underneath. Although the use of ultra-short pulse lengths and UV wavelength minimizes the depth of silicon that is affected, some damage is still present. FIG. 5 is a representative pattern of the distributed selective emitter and base openings with contacts centrally located inside these regions. FIGS. 6 A and 6B are SEM micrographs showing selective emitter and selective base openings, and contacts within these openings, respectively. These ablation spots were made using a laser with 10 picoseconds pulse length and UV wavelength. Still, some surface damage can be seen.

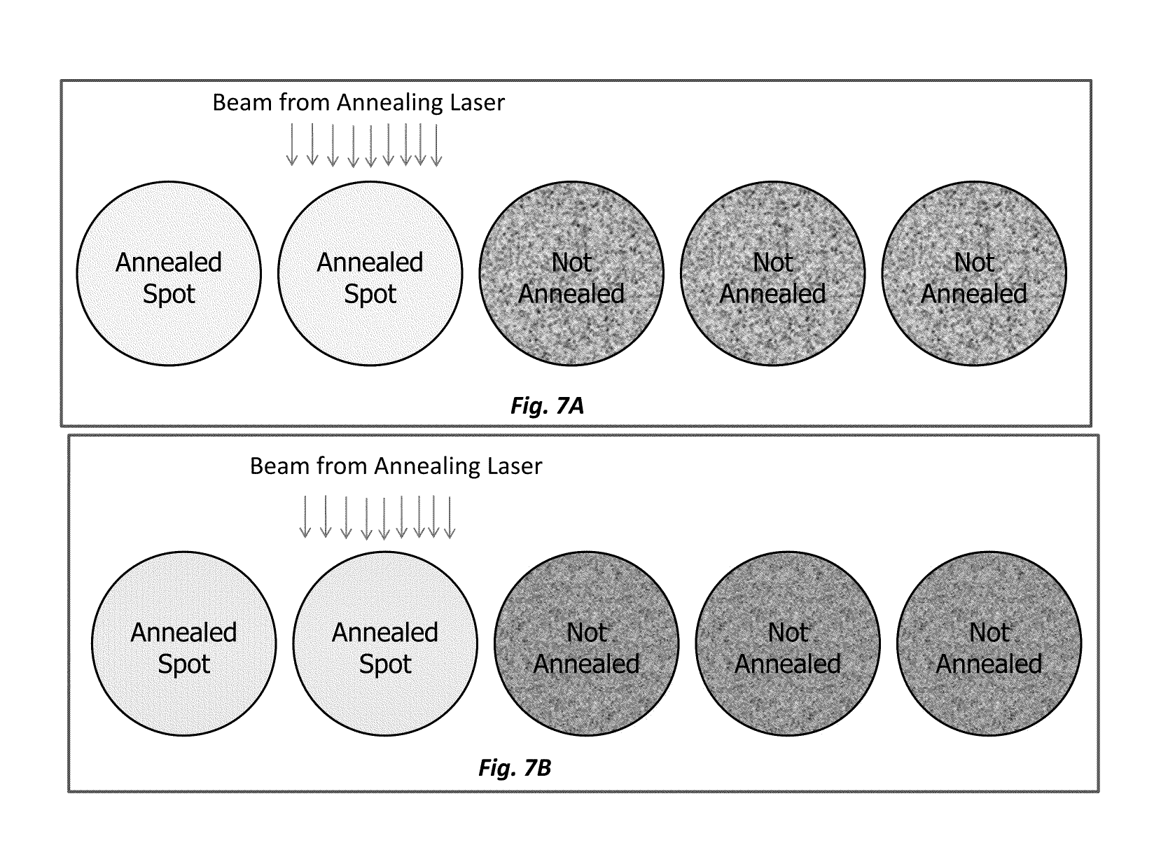

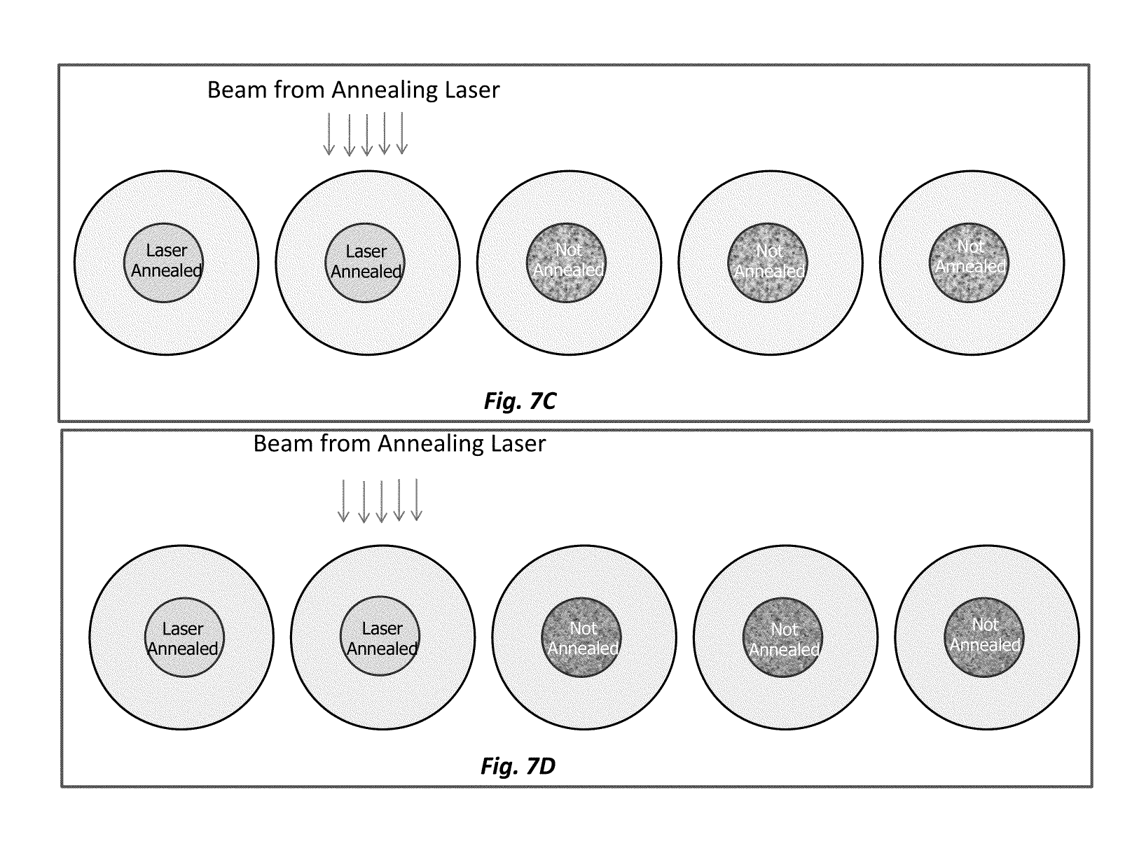

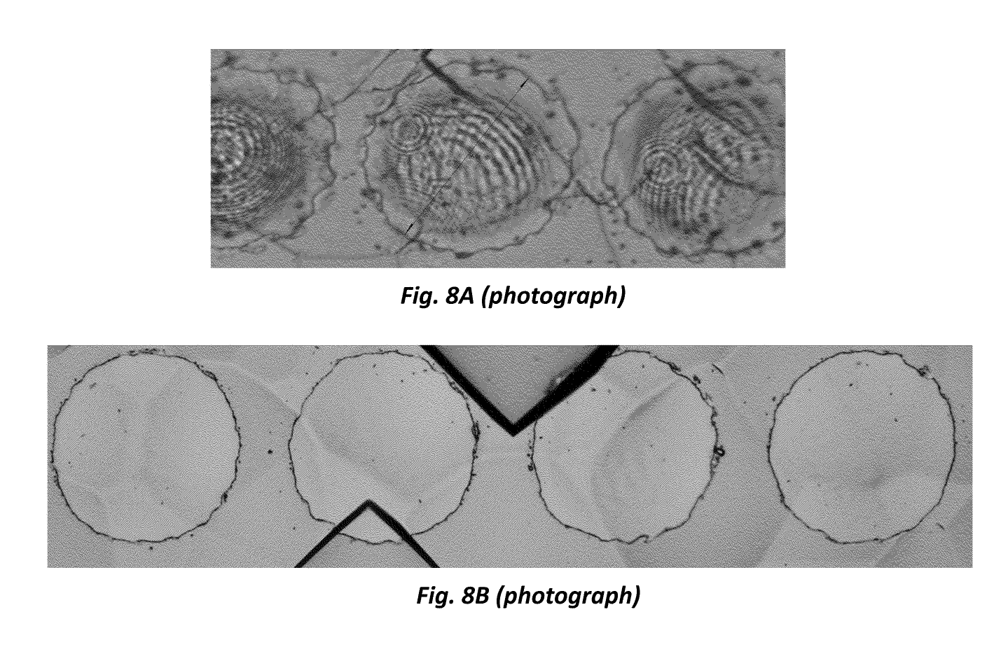

As disclosed herein, the annealing of the ablated region to reduce or eliminate the damage that occurs during the ablation process. After the pulsed laser ablation is complete, the ablated area is annealed using another suitable pulsed laser beam that anneals out the damage. For the distributed selective emitter and base openings, each ablation spot is annealed, using synchronized laser triggering from the annealing laser. For annealing, a suitable laser typically has pulse length in the long nanoseconds range, such as preferably in the range of approximately 10 to 500 nanoseconds, and wavelength of 532 nm. However, other lasers with even shorter or longer pulse length and other wavelengths could be used depending on the extent of the ablation laser damage to be annealed. FIGS. 7A and 7B show schematically the spot by spot annealing of damaged silicon in selective emitter (SE) and selective base (SB) ablations while FIGS. 7C and 7D, show similar spot by spot annealing of the laser damage in the contact ablation area using laser annealing. The corresponding optical micrographs are shown in FIGS. 8A and 8B. FIG. 8A shows the laser ablation spots before laser annealing, while FIG. 8B shows the spots after laser annealing. The elimination of laser damage in the ablation spots by laser annealing can be clearly seen.

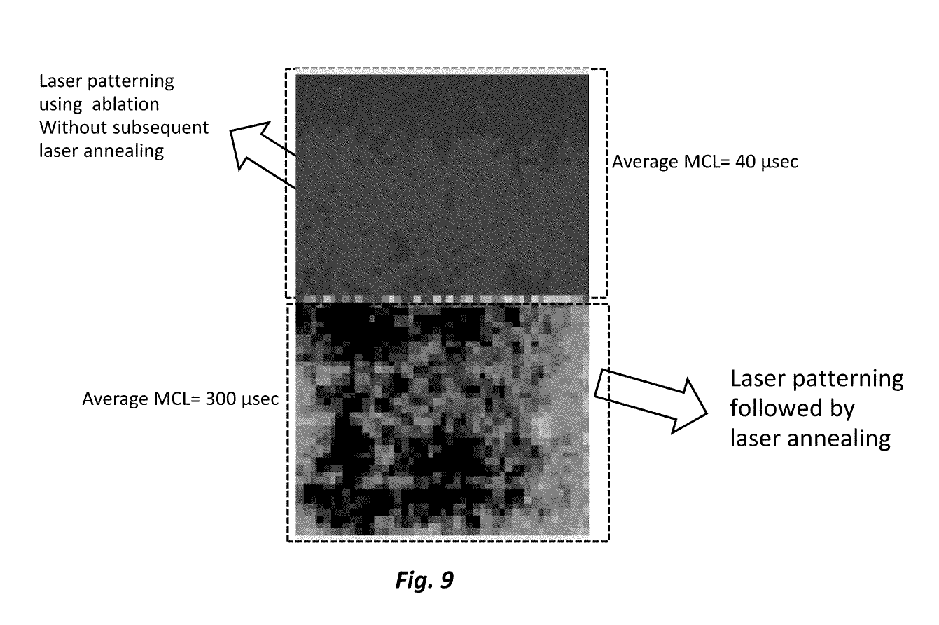

FIG. 9 shows the improved effective minority carrier lifetime (MCL) obtained upon laser annealing; one-half of a wafer patterned by laser ablation as compared to the half that did not receive the laser annealing treatment.

In one scheme the laser anneal of the ablated regions is carried out with at least one doped oxide layer covering the ablated regions. In this case the melting on silicon during laser annealing results in melt incorporation or absorption of p-type (boron, for example) and n-type dopant (phosphorous, for example) from the overlying BSG and PSG films into molten silicon, respectively. This provides a high concentration of these dopants in the vicinity of the surface in addition to the dopants that are driven in by the furnace anneal and have a diffused error function profile from a relatively fixed dopant source. This results in the high-low junction for these doped junctions resulting in reduced carrier absorption at the silicon surface thereby improving the cell efficiency.

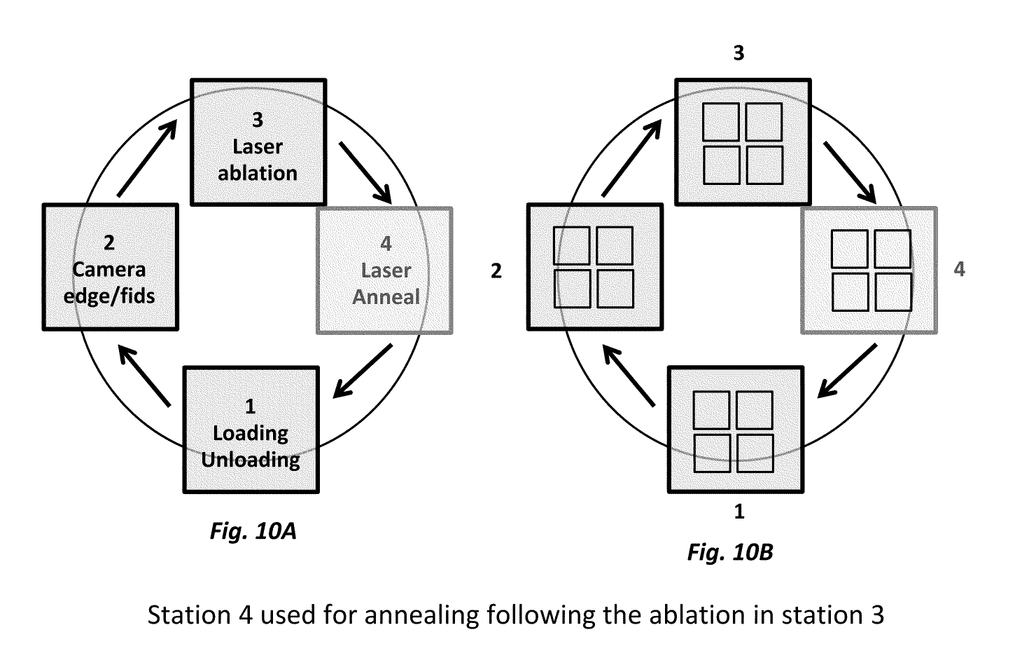

A suitable laser apparatus configuration that is highly cost-effective, is a multi-station platform that provides for parallel processing at different stations. FIG. 10 shows the configuration of a tool having four stations. The wafer is rotated from one chuck to another where a different step of the ablation/annealing process is carried out. As shown in FIG. 10, the wafer is loaded in station 1, moved to station 2 for fiducial detection for accuracy of laser ablation patterning and aligned laser annealing. The laser ablation is carried out in station 3 followed by annealing in station 4. It should be noted that this scheme provides for parallel processing on different chucks, the throughput being controlled by the slowest process in this sequence. To improve the throughput the number of wafers on the chuck can be increased with concurrent increase in the laser ablation and laser annealing to multi-wafer capability. FIG. 10B shows 4 wafers per chuck.

Application of an Ablation Mask to Prevent Laser Ablation Damage.

A scheme where a thin layer of mask material is used to absorb the laser beam during ablation to prevent the laser damage is disclosed herein. Regions so opened (where the mask material is removed) can now be further opened to silicon by wet etching the dielectric layer underneath. In effect, in this scheme the thin layer of mask is patterned first using the ablation laser, the pattern then transferred to silicon by wet etching of the dielectric in the opening. Since, the intensity of laser beam reaching the silicon substrate is low, there is no laser damage and the silicon minority carrier lifetimes (MCT) are not affected. Any non-conducting film that is resistant to the wet etching used to pattern the dielectric can be used as a mask.

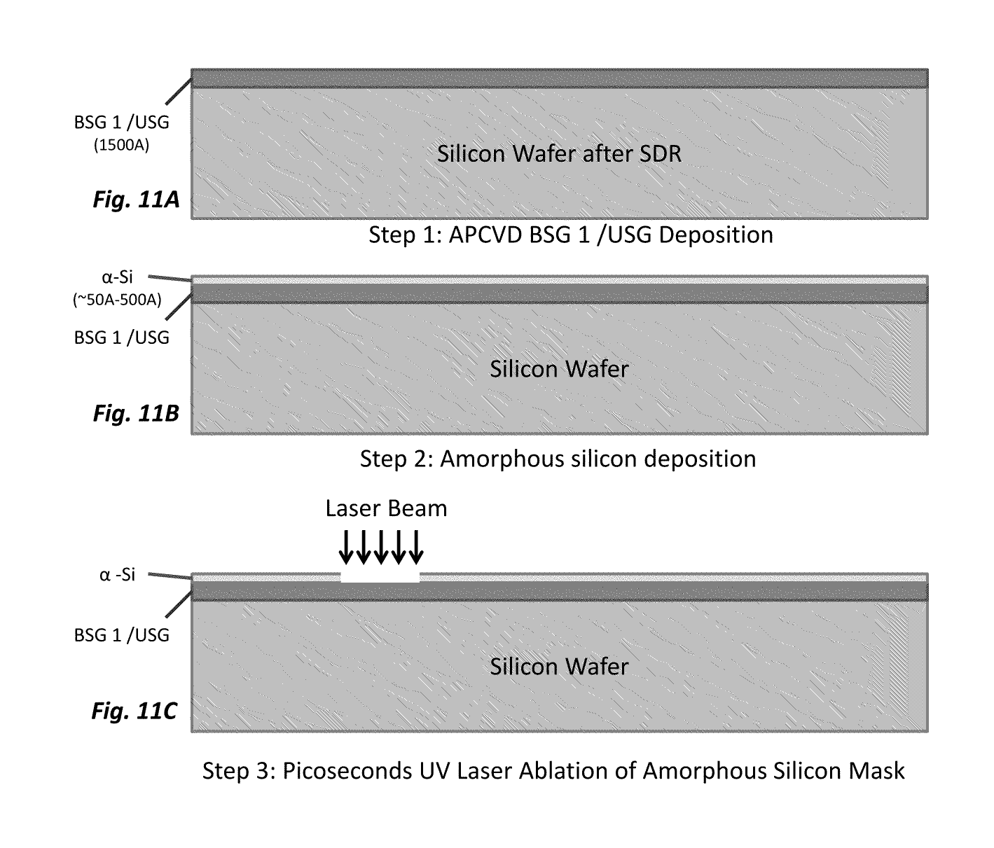

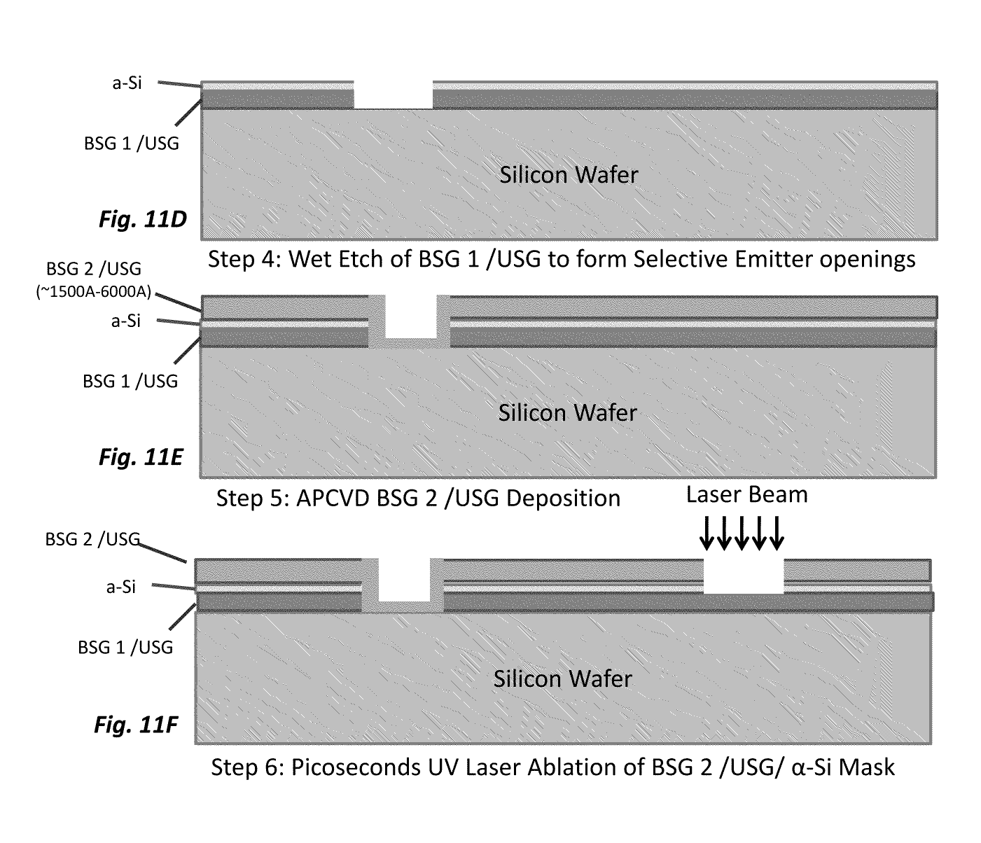

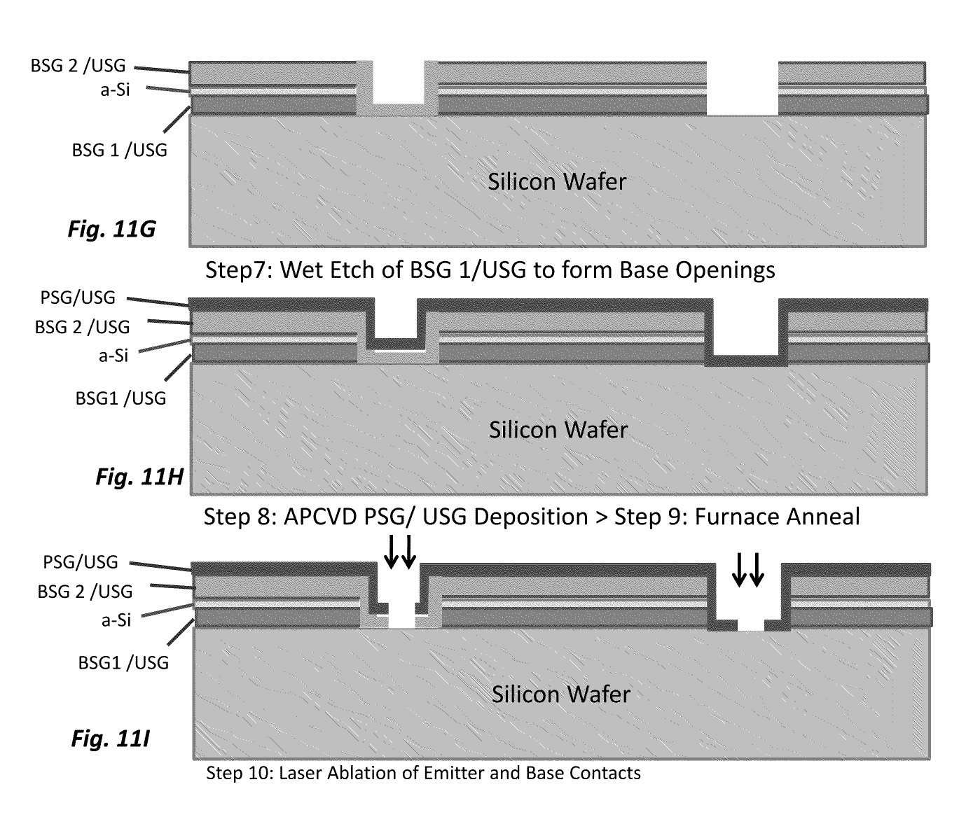

FIGS. 11A to 11I schematically outline the solar cell structure in the process steps where a thin layer of amorphous silicon (α-Si) is used as the patterning mask for laser ablation.

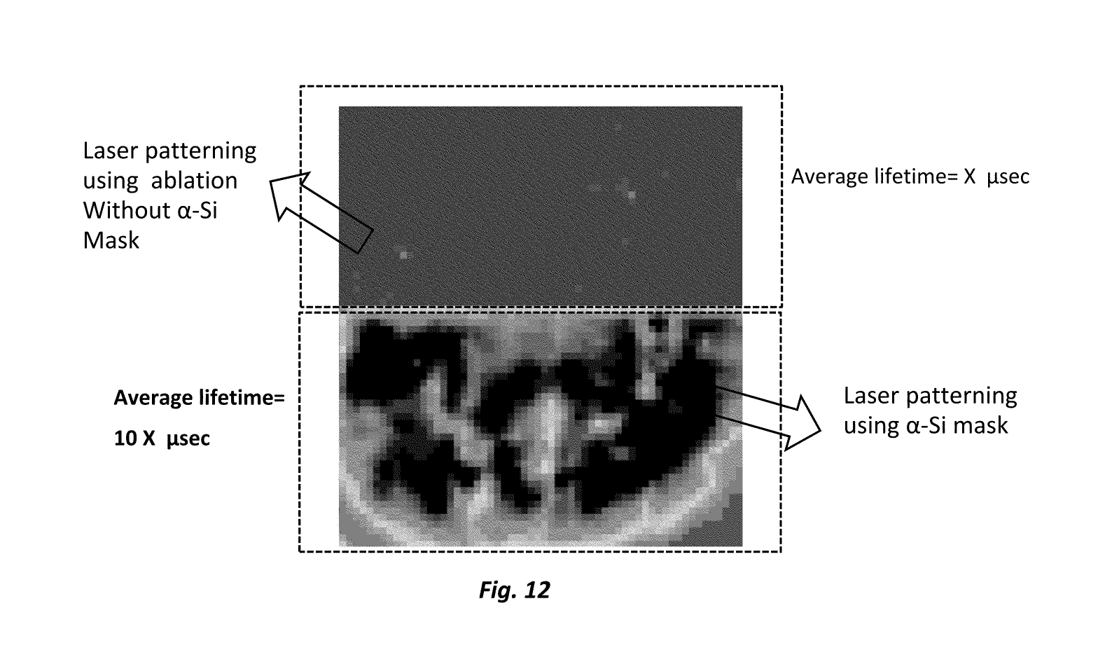

FIG. 12 shows the minority carrier lifetime map of a wafer where the top half did not use the ablation mask scheme, while the lower half used the α-Si mask scheme. No lifetime degradation was seen in the lower half of the wafer.

The disclosed subject matter may be applied directly to the formation of high-efficiency back-contact, back-junction solar cells utilizing multi-layer backside metallization. As compared to front-contact solar cells, all back-junction, back-contact solar cells have all metallization (both base and emitter metallization and busbars) positioned on the backside of the cell and may eliminate sunlight shading due to metal runners on the front/sunnyside surface of the cell (optical shading losses of emitter metal fingers and busbars in the case of traditional front-contact solar cells). And while metallization (both the base and the emitter contacts) of the cells may be formed on the same side (opposite the sunnyside) to eliminate the optical shading losses, cell metallization complexity may be increased in some back contact designs as both the base and emitter electrodes have to be contacted on the same side. (However, in some instances same side base and emitter contacts may simplify solar cell interconnections at the module level).

In some instances, an interdigitated metallization scheme requiring high metal pattern fidelity may be used. And as metallization pattern geometries may be formed increasingly smaller to increase cell efficiencies, the required thickness of the metallization layer may also significantly increase—for example 30 to 60 microns for a high conductivity metallization layer, such as copper or aluminum, on solar cells with dimensions of 125 mm×125 mm to 156 mm×156 mm.

Further, to reduce required metallization thickness, cell metallization may be partitioned into two metal layers/levels and a backplane material (such as a polymer sheet) may be formed between the two metallization layers to help reduce stress induced from the thicker higher-conductance second metallization level. In other words, the backplane material separates the two metallization layers and provides structural support to the solar cell substrate allowing for scaling to large area back-contact solar cells. Thus, each layer—first metallization layer, backplane material, and second metallization layer—may be optimized separately for cost and performance. And in some dual-level metallization embodiments, the two metal levels are patterned orthogonally with to each other, with the second (last) metal level having far fewer and coarser fingers than the first (on-cell) metal level.

And although the following exemplary back junction back contact solar cell designs and manufacturing processes described herein may utilize two levels of metallization (dual layer metallization) which are separated by an electrically insulating and mechanically supportive backplane layer, the disclosed subject matter may be applicable in any fabrication embodiment requiring real-time in-situ process laser via drilling end-point detection including multi-level metallization patterns and metallization layers comprising metallization stacks (for example a first level metallization layer of Al/NiV/Sn). In some instances any combination of the backplane and metallization layers may serve as permanent structural support/reinforcement and provide embedded high-conductivity (aluminum and/or copper) interconnects for a high-efficiency thin crystalline silicon solar cell without significantly compromising solar cell power or adding to solar cell manufacturing cost. Laser processes using schemes for producing solar cells with high efficiency, and particularly thin-film crystalline silicon solar cells based sub-50-micron thick silicon substrates, are provided herein.

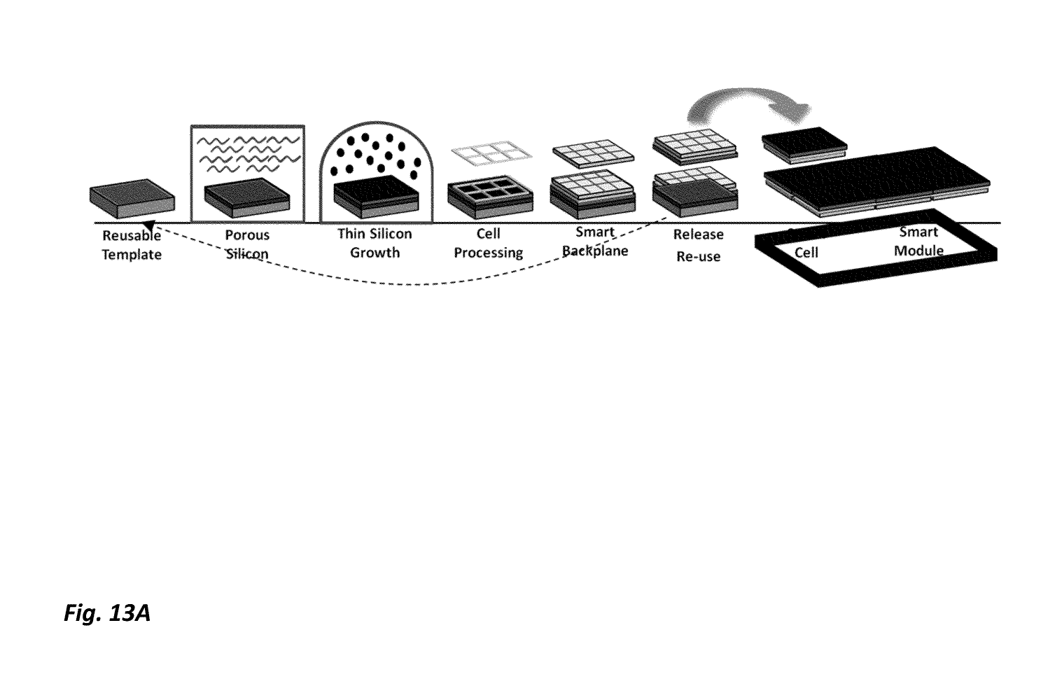

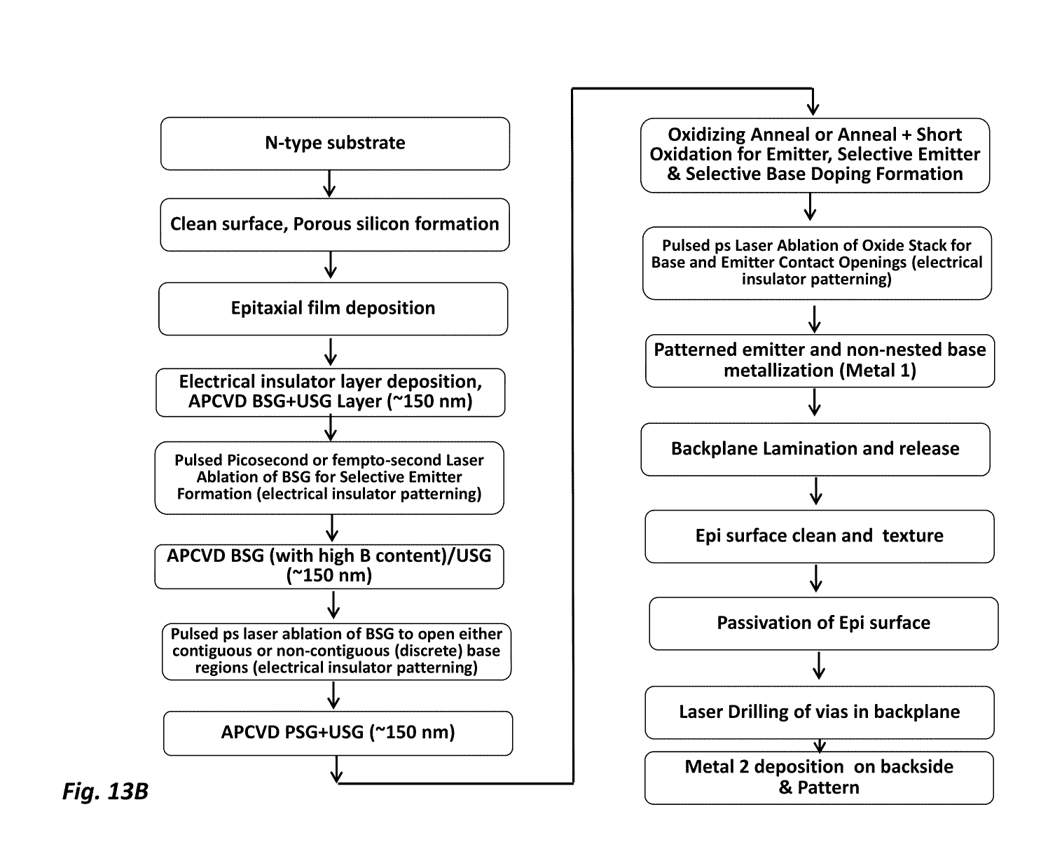

In some instances, the non-nested base region designs and methods disclosed herein may be applied to and integrated with current back-contact back-junction solar cell structures and fabrication processes. FIG. 13A is a general process flow, for example, for the formation of a back-contact back-junction solar cell which may utilize the non-nested base regions. Specifically, FIG. 13A is a general process flow highlighting key processing of a tested thin-crystalline-silicon solar cell manufacturing process using thin epitaxial silicon lift-off processing which substantially reduces silicon usage and eliminates traditional manufacturing steps to create low-cost, high-efficiency, back-junction/back-contact monocrystalline cells. The process flow of FIG. 13A shows the fabrication of solar cells having laminated backplanes for smart cell and smart module design formed using a reusable template and epitaxial silicon deposition on a release layer of porous silicon which may utilize and integrate the non-nested base region designs and formation methods as disclosed herein.

The process shown in FIG. 13A starts with a reusable silicon template, typically made of a p-type monocrystalline silicon wafer, onto which a thin sacrificial layer of porous silicon is formed (for example by an electrochemical etch process through a surface modification process in an HF/IPA wet chemistry in the presence of an electrical current). The starting material or reusable template may be a single crystalline silicon wafer, for example formed using crystal growth methods such as FZ, CZ, MCZ (Magnetic stabilized CZ), and may further comprise epitaxial layers grown over such silicon wafers. The semiconductor doping type may be either p or n and the wafer shape, while most commonly square shaped, may be any geometric or non-geometric shape such as quasi-square or round.

Upon formation of the sacrificial porous silicon layer, which serves both as a high-quality epitaxial seed layer as well as a subsequent separation/lift-off layer, a thin layer (for example a layer thickness in the range of a few microns up to about 70 microns, or a thickness less than approximately 50 microns) of in-situ-doped monocrystalline silicon is formed, also called epitaxial growth. The in-situ-doped monocrystalline silicon layer may be formed, for example, by atmospheric-pressure epitaxy using a chemical-vapor deposition or CVD process in ambient comprising a silicon gas such as trichlorosilane or TCS and hydrogen.

Prior to backplane lamination, the solar cell base and emitter contact metallization pattern is formed directly on the cell backside, for instance using a thin layer of screen printed or sputtered (PVD) or evaporated aluminum (or aluminum silicon alloy or Al/NiV/Sn stack) material layer. This first layer of metallization (herein referred to as M1) defines the solar cell contact metallization pattern, for example fine-pitch interdigitated back-contact (IBC) conductor fingers defining the base and emitter regions of the IBC cell. The M1 layer extracts the solar cell current and voltage and transfers the solar cell electrical power to the second level/layer of higher-conductivity solar cell metallization (herein referred to as M2) formed after M1.

After completion of a majority of solar cell processing steps, a very-low-cost backplane layer may be bonded to the thin epi layer for permanent cell support and reinforcement as well as to support the high-conductivity cell metallization of the solar cell. The backplane material may be made of a thin (for instance, a thickness in the range of approximately 50 to 250 microns and in some instances in the range of 50 to 150 microns), flexible, and electrically insulating polymeric material sheet such as an inexpensive prepreg material commonly used in printed circuit boards which meets cell process integration and reliability requirements. The mostly-processed back-contact, back-junction backplane-reinforced large-area (for instance, a solar cell area of at least 125 mm×125 mm, 156 mm×156 mm, or larger) solar cell is then separated and lifted off from the template along the mechanically-weakened sacrificial porous silicon layer (for example through a mechanical release MR process) while the template may be re-used many times to further minimize solar cell manufacturing cost. Final cell processing may then be performed on the solar cell sunny-side which is exposed after being released from the template. Sunny-side processing may include, for instance, completing frontside texturization and passivation and anti-reflection coating deposition process.

As described with reference to the flow outlined in FIG. 13A, after formation of the backplane (on or in and around M1 layer), subsequent detachment of the backplane-supported solar cell from the template along the mechanically weak sacrificial porous silicon layer, and completion of the frontside texture and passivation processes, a higher conductivity M2 layer is formed on the backplane. Via holes (in some instances up to hundreds or thousands of via holes) are drilled into the backplane (for example by laser drilling) and may have diameters in the range of approximately 50 up to 500 microns. These via holes land on pre-specified regions of M1 for subsequent electrical connections between the patterned M2 and M1 layers through conductive plugs formed in these via holes. Subsequently or in conjunction with the via holes filling and conductive plug formation, the patterned higher-conductivity metallization layer M2 is formed (for example by plasma sputtering, plating, evaporation, or a combination thereof—using an M2 material comprising aluminum, Al/NIV, Al/NiV/Sn, or copper). For an interdigitated back-contact (IBC) solar cell with fine-pitch IBC fingers on M1 (for instance, hundreds of fingers), the patterned M2 layer may be designed orthogonal to M1—in other words rectangular or tapered M2 fingers are essentially perpendicular to the M1 fingers. Because of this orthogonal transformation, the M2 layer may have far fewer IBC fingers than the M1 layer (for instance, by a factor of about 10 to 50 fewer M2 fingers). Hence, the M2 layer may be formed in a much coarser pattern with wider IBC fingers than the M1 layer. Solar cell busbars may be positioned on the M2 layer, and not on the M1 layer (in other words a busbarless M1), to eliminate electrical shading losses associated with on-cell busbars. As both the base and emitter interconnections and busbars may be positioned on the M2 layer on the solar cell backside backplane, electrical access is provided to both the base and emitter terminals of the solar cell on the backplane from the backside of the solar cell.

The backplane material formed between M1 and M2 may be a thin sheet of a polymeric material with sufficiently low coefficient of thermal expansion (CTE) to avoid causing excessive thermally induced stresses on the thin silicon layer. Moreover, the backplane material should meet process integration requirements for the backend cell fabrication processes, in particular chemical resistance during wet texturing of the cell frontside and thermal stability during the PECVD deposition of the frontside passivation and ARC layer. The electrically insulating backplane material should also meet the module-level lamination process and long-term reliability requirements. While various suitable polymeric (such as plastics, fluropolymers, prepregs, etc.) and suitable non-polymeric materials (such as glass, ceramics, etc.) may be used as the backplane material, backplane material choice depends on many considerations including, but not limited to, cost, ease of process integration, reliability, pliability, etc.

A suitable material choice for the backplane material is prepreg. Prepreg sheets are used as building blocks of printed circuit boards and may be made from combinations of resins and CTE-reducing fibers or particles. The backplane material may be an inexpensive, low-CTE (typically with CTE<10 ppm/° C., or with CTE<5 ppm/° C.), thin (for example 50 to 250 microns, and more particularly in the range of about 50 to 150 microns) prepreg sheet which is relatively chemically resistant to texturization chemicals and is thermally stable at temperatures up to at least 180° C. (or as high as at least 280° C.). The prepreg sheet may be attached to the solar cell backside while still on the template (before the cell lift off process) using a vacuum laminator. Upon applying heat and pressure, the thin prepreg sheet is permanently laminated or attached to the backside of the processed solar cell. Then, the lift-off release boundary is defined around the periphery of the solar cell (near the template edges), for example by using a pulsed laser scribing tool, and the backplane-laminated solar cell is then separated from the reusable template using a mechanical release or lift-off process. Subsequent process steps may include: (i) completion of the texture and passivation processes on the solar cell sunnyside, (ii) completion of the solar cell high conductivity metallization on the cell backside (which may comprise part of the solar cell backplane). The high-conductivity metallization M2 layer (for example comprising aluminum, copper, or silver) comprising both the emitter and base polarities is formed on the laminated solar cell backplane.

Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temperature prepregs may be fully cured by using vacuum bag pressure alone at much lower temperatures.

FIG. 13B is a representative manufacturing process flow for forming a back-contact/back-junction cell using epitaxial silicon lift-off processing may comprise the following fabrication steps: 1) start with reusable template; 2) form porous silicon on template (for example bilayer porous Si using anodic etch); 3) deposit epitaxial silicon with in-situ doping; 4) perform back-contact/back-junction cell processing while on template including M1 formation; 5) laminate backplane sheet on back-contact cell, laser scribe release border around the backplane into epitaxial silicon layer, and cell release; 7) proceed with performing back-end processes including: wet silicon etch/texture/clean, PECVD sunnyside and trench edge passivation, laser drilling of via holes in backplane, PVD deposition or evaporation of metal (—Al), or plating (Cu) for M2, and final laser ablation to complete M2 patterning.

The described process flows of FIGS. 13A and 13B result in a solar cell formed on an epitaxially deposited thin silicon film with an exemplary thickness in the range of approximately 10 up to about 100 microns which may be easily and advantageously integrated with the non-nested base designs disclosed herein.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein. And it is intended that all such additional systems, methods, features, and advantages that are included within this description be within the scope of the claims.

What is claimed is:

1. A back contact, back-junction crystalline semiconductor solar cell, comprising:
a crystalline semiconductor substrate, said substrate comprising a light receiving passivated frontside surface and a passivated backside surface comprising patterned interdigitated doped emitter and base regions;
a patterned electrical insulator layer on said backside surface, said patterned electrical insulator layer comprising a doped layer proximate said backside surface and an undoped capping layer on said doped layer; and
a contact metallization pattern comprising emitter metallization electrodes contacting said emitter regions and non-nested base metallization electrodes contacting said base regions, said non-nested base metallization electrodes go beyond said base regions to overlap at least a portion of said patterned insulator without causing electrical shunts in said solar cell.

2. The back contact crystalline semiconductor solar cell of claim 1, wherein said emitter and base metallization electrodes comprise aluminum.

3. The back contact crystalline semiconductor solar cell of claim 1, wherein said emitter and base metallization electrodes comprise aluminum silicon.

4. The back contact crystalline semiconductor solar cell of claim 1, wherein said emitter and base metallization electrodes have an interdigitated pattern.

5. The back contact crystalline semiconductor solar cell of claim 1, wherein said solar cell uses a second patterned metallization layer separated from said contact metallization pattern by an electrically insulating backplane.

6. The back contact crystalline semiconductor solar cell of claim 1, wherein said patterned electrical insulator layer comprises a combination of at least a doped glass layer and an undoped glass layer.

7. The back contact crystalline semiconductor solar cell of claim 1, wherein said patterned electrical insulator layer comprises a combination of a first layer of borosilicate glass and a second layer of phosphorous silicate glass.

8. The back contact crystalline semiconductor solar cell of claim 1, wherein said patterned electrical insulator layer comprises a combination of a first layer of borosilicate glass, a second layer of borosilicate glass, and a phosphorous silicate glass.

9. A back contact, back-junction crystalline semiconductor solar cell, comprising:
a crystalline semiconductor substrate, said substrate comprising a light receiving passivated frontside surface and a passivated backside surface comprising doped emitter and non-contiguous discrete base regions;
a patterned electrical insulator layer on said backside surface, said patterned electrical insulator layer comprising a doped layer proximate said backside surface and an undoped capping layer on said doped layer; and
a contact metallization pattern comprising emitter metallization electrodes contacting said emitter regions and non-nested base metallization electrodes contacting said base regions, said non-nested base metallization electrodes go beyond said base regions to overlap at least a portion of said patterned insulator without causing electrical shunts in said solar cell.

10. The back contact crystalline semiconductor solar cell of claim 9, wherein said emitter and base metallization electrodes comprise aluminum.

11. The back contact crystalline semiconductor solar cell of claim 9, wherein said emitter and base metallization electrodes comprise aluminum silicon.

12. The back contact crystalline semiconductor solar cell of claim 9, wherein said emitter and base metallization electrodes have an interdigitated pattern.

13. The back contact crystalline semiconductor solar cell of claim 9, wherein said solar cell uses a second patterned metallization layer separated from said contact metallization pattern by an electrically insulating backplane.

14. The back contact crystalline semiconductor solar cell of claim 9, wherein said patterned electrical insulator layer comprises a combination of at least a doped glass layer and an undoped glass layer.

15. The back contact crystalline semiconductor solar cell of claim 9, wherein said patterned electrical insulator layer comprises a combination of a first layer of borosilicate glass and a second layer of phosphorous silicate glass.

16. The back contact crystalline semiconductor solar cell of claim 9, wherein said patterned electrical insulator layer comprises a combination of a first layer of borosilicate glass, a second layer of borosilicate glass, and a phosphorous silicate glass.

17. A method for forming a back-contact, back-junction crystalline semiconductor solar cell, comprising:
forming patterned interdigitated doped emitter and base regions on a backside surface of a crystalline semiconductor substrate;
forming patterned electrically insulating layer stack comprising a combination of at least a doped layer and an undoped capping layer on said patterned doped emitter and base regions;
forming a contact metallization pattern comprising emitter metallization electrodes contacting said emitter regions and non-nested base metallization electrodes contacting said base regions, said non-nested base metallization electrodes go beyond said base regions to overlap at least a portion of said patterned insulator without causing electrical shunts in said solar cell.

18. The method for forming a back contact, back-junction solar cell of claim 17, wherein said electrically insulating layer stack is formed according to a chemical vapor deposition process.

19. The method for forming a back contact, back-junction solar cell of claim 17, wherein said electrically insulating layer stack is formed using an atmospheric pressure chemical vapor deposition process.

20. The method for forming a back contact, back-junction solar cell of claim 17, wherein said electrically insulating layer comprises a combination of at least a doped oxide layer and an undoped oxide layer.
